(19) United States
(12) Patent Application Publication
(10) Pub. No.: US 2015/0093882 A1
(43) Pub. Date: Apr. 2, 2015

(54) WAFER PROCESSING METHOD

(71) Applicant: DISCO CORPORATION, Tokyo (JP)

(72) Inventor: Kazuhisa Arai, Tokyo (JP)

(21) Appl. No.: 14/488,882

(22) Filed: Sep. 17, 2014

(30) Foreign Application Priority Data
Oct. 2, 2013 (JP) 2013-207467

(51) Int. Cl. H01L 21/78

(52) U.S. Cl. CPC H01L 21/78
USPC 438/462

(57) ABSTRACT

A wafer processing method of processing a wafer having a plurality of devices formed on the front side of the wafer, the devices being respectively formed in a plurality of separate regions defined by a plurality of crossing division lines. The wafer processing method includes a support member providing step of providing a support member on the back side of the wafer, the support member having substantially the same size as that of the wafer, and a dividing step of dicing the wafer from the front side thereof along the division lines after performing the support member providing step, thereby dividing the wafer into a plurality of chips.

### BACKGROUND OF THE INVENTION

1. Field of the Invention

The present invention relates to a wafer processing method of processing a wafer having a plurality of devices formed on the front side of the wafer.

2. Description of the Related Art

A wafer having a plurality of devices such as ICs formed on the front side of the wafer is cut by a cutting apparatus including an annular cutting blade or by a laser processing apparatus including a processing head for applying a laser beam, thereby dividing the wafer into a plurality of chips respectively corresponding to the plural devices.

In cutting (dicing) the wafer, a dicing tape is preliminarily attached to the back side of the wafer and an annular frame is preliminarily fixed to the peripheral portion of the dicing tape (see Japanese Patent Laid-open No. 2003-243483, for example). Accordingly, scattering of the chips after dicing the wafer can be prevented to thereby maintain the handleability of the wafer.

### SUMMARY OF THE INVENTION

In recent years, increasing the diameter of a wafer has been promoted, which causes a problem such that a wafer processing apparatus becomes large in size. It is therefore an object of the present invention to provide a wafer processing method which can reduce the size of a wafer processing apparatus.

In accordance with an aspect of the present invention, there is provided a wafer processing method of processing a wafer having a plurality of devices formed on the front side of the wafer, the devices being respectively formed in a plurality of separate regions defined by a plurality of crossing division lines, the wafer processing method including a support member providing step of providing a support member on the back side of the wafer, the support member having substantially the same size as that of the wafer; and a dividing step of dicing the wafer from the front side thereof along the division lines after performing the support member providing step, thereby dividing the wafer into a plurality of chips.

Preferably, the support member includes a plate, and the support member providing step includes the step of providing the plate on the back side of the wafer with an adhesive member interposed therebetween.

In the wafer processing method according to the present invention, the support member having substantially the same size as that of the wafer is provided on the back side of the wafer. In this condition, the wafer supported to the support member is divided into the plural chips by dicing. Accordingly, it is not necessary to use an annular frame for supporting a wafer as in the conventional processing method. That is, the annular frame having a diameter larger than that of the wafer is not required in the present invention, so that a processing apparatus for performing the wafer processing method can be reduced in size.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically showing a support member providing step according to a preferred embodiment of the present invention;

FIG. 2 is a perspective view schematically showing a dividing step according to this preferred embodiment; and

FIG. 3 is a perspective view schematically showing a support member providing step using a support member according to a modification.

### DETAILED DESCRIPTION OF THE PREFERRED EMBODIMENT

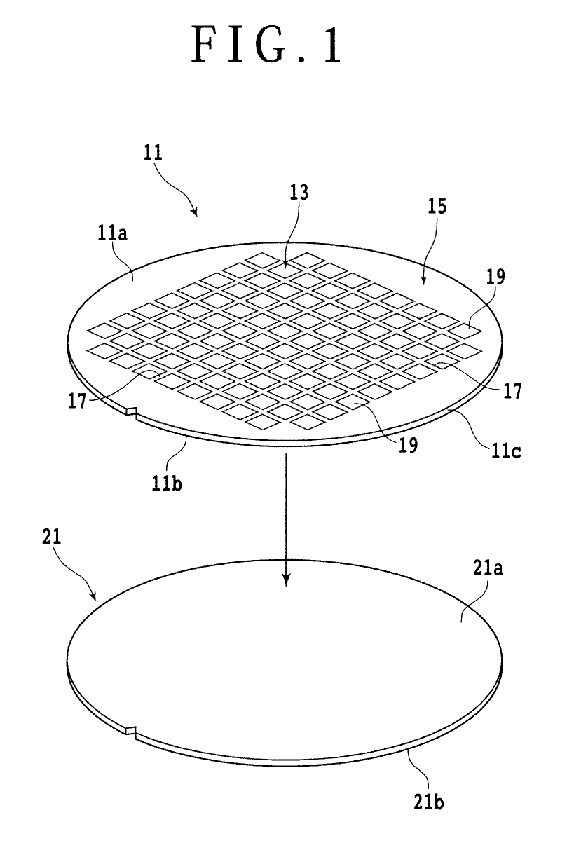

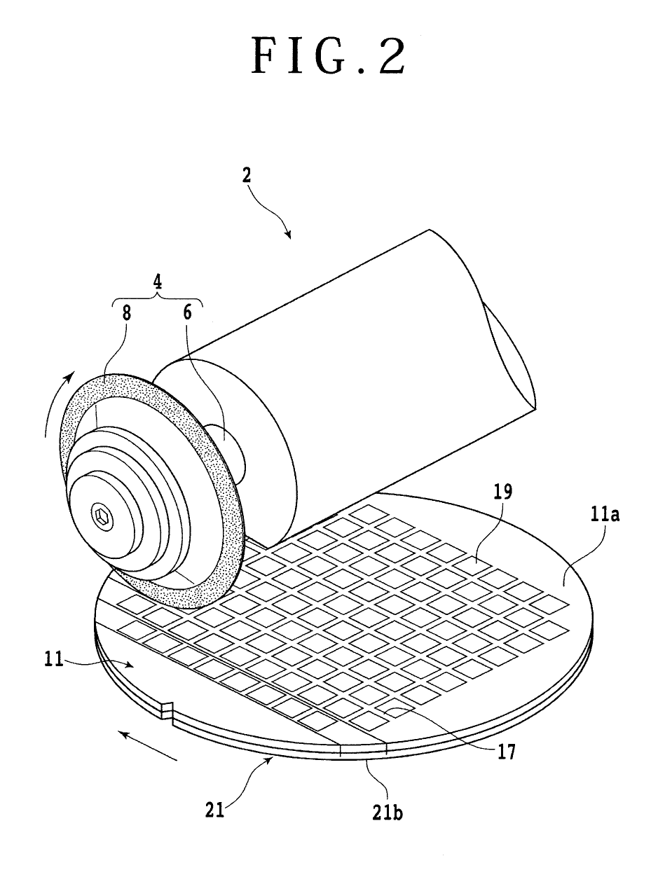

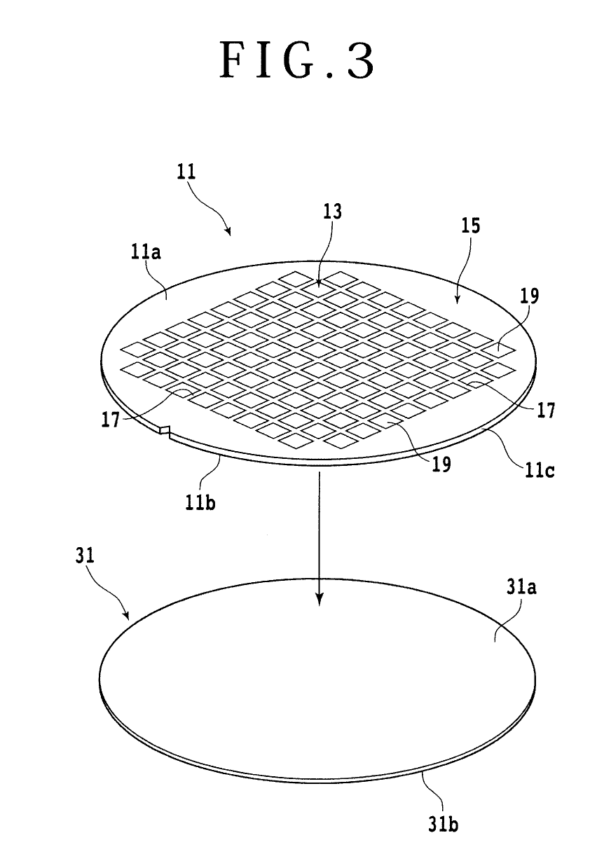

A preferred embodiment of the present invention will now be described with reference to the attached drawings. The wafer processing method according to this preferred embodiment includes a support member providing step (see FIG. 1 or 3) and a dividing step (see FIG. 2). The support member providing step is the step of providing a support member on the back side of a wafer having a plurality of devices formed on the front side of the wafer, the support member having substantially the same size as that of the wafer. The dividing step is the step of dicing the wafer from the front side thereof to divide the wafer into a plurality of chips. The wafer processing method according to this preferred embodiment will now be described in more detail.

FIG. 1 is a perspective view schematically showing the support member providing step according to this preferred embodiment. In FIG. 1, reference numeral 11 denotes a wafer as a workpiece. The wafer 11 is a disk-shaped semiconductor wafer, for example. The wafer 11 has a front side 11a and a back side 11b. The front side 11a of the wafer 11 is composed of a central device area 13 and a peripheral marginal area 15 surrounding the device area 13. The device area 13 is partitioned by a plurality of crossing streets (division lines) 17 to define a plurality of separate regions where a plurality of devices 19 such as ICs are respectively formed. The wafer 11 has an outer circumference 11c. The outer circumference 11c of the wafer 11 is a chamfered portion having an arcuate cross section.

In the wafer processing method according to this preferred embodiment, the support member providing step is first performed in such a manner that a support member 21 is provided on the back side 11b of the wafer 11 as shown in FIG. 1. In this preferred embodiment, the support member 21 is a circular plate having substantially the same size as that of the wafer 11. The support member 21 has a predetermined rigidity. More specifically, the size of the support member 21 may be completely the same as that of the wafer 11 or may be slightly greater than that of the wafer 11 within the range of tens of millimeters (typically, 30 mm or less).

For example, a semiconductor wafer similar to the wafer 11 may be used as the support member 21. In this case, a cutting blade included in a cutting apparatus may be preferably used to cut the support member 21 in the subsequent step. That is, even when the cutting blade is driven to cut through the wafer 11 into the support member 21, there is no possibility that the cutting blade may be damaged. However, any circular plate capable of suitably supporting the wafer 11 may be used as the support member 21. For example, a glass substrate, metal substrate, or resin substrate may be used as the support member 21.

In performing the support member providing step, an adhesive member (not shown) is first provided on the back side 11b of the wafer 11 or on the front side 21a of the support member 21. Examples of the adhesive member include an adhesive material and a double-sided adhesive tape. Typical examples of the adhesive material include thermosetting resin and photocuring resin. Thereafter, the wafer 11 and the support member 21 are superimposed on each other in such a manner that the back side 11b of the wafer 11 faces the front side 21a of the support member 21. Accordingly, the support member 21 is fixed through the adhesive member to the back side 11b of the wafer 11.

After performing the support member providing step, the dividing step is performed in such a manner that the wafer 11 is cut along the streets 17 and thereby divided into a plurality of chips respectively corresponding to the plural devices 19 (dicing step). FIG. 2 is a perspective view schematically showing the dividing step according to this preferred embodiment.

In this preferred embodiment, the dividing step is performed by using a cutting apparatus (processing apparatus) 2 shown in FIG. 2. As shown in FIG. 2, the cutting apparatus 2 includes a cutting unit (processing unit) 4 for cutting the wafer 11. This cutting unit 4 includes a spindle 6 supported so as to be rotatable about a horizontal axis and an annular cutting blade 8 mounted on one end of the spindle 6. A motor (not shown) is connected to the other end of the spindle 6, so as to rotationally drive the spindle 6, thereby rotating the cutting blade 8. A chuck table (not shown) is provided below the cutting unit 4. The chuck table has an upper surface as a holding surface for holding the wafer 11 under suction. A suction passage (not shown) is formed in the chuck table so as to communicate with the holding surface. This suction passage is connected to a vacuum source (not shown). Accordingly, a vacuum generated in the vacuum source is applied through the suction passage to the holding surface of the chuck table.

In performing the dividing step, the unit of the wafer 11 and the support member 21 is first placed on the chuck table in the condition where the back side 21b of the support member 21 is in contact with the holding surface of the chuck table. Thereafter, the vacuum generated in the vacuum source is applied to the holding surface of the chuck table. As a result, the wafer 11 is held through the support member 21 on the holding surface of the chuck table under suction in the condition where the front side 11a of the wafer 11 is exposed. Thereafter, the cutting blade 8 is positioned at one end of a predetermined one of the streets 17 as a cutting start position. At this position, the cutting blade 8 is rotated and lowered to cut into the wafer 11 held on the chuck table. Thereafter, the cutting blade 8 and the chuck table are relatively moved (fed) in a first direction parallel to the predetermined street 17 (feeding operation). In this preferred embodiment, the chuck table is moved in the first direction with the cutting blade 8 fixed in position. The depth of cut into the wafer 11 by the cutting blade 8 is set so that the wafer 11 is fully cut. More specifically, the depth of cut is set so that the cutting blade 8 reaches the interface between the wafer 11 and the support member 21 or reaches the front side 21a of the support member 21. Accordingly, the wafer 11 can be divided along the predetermined street 17.

After dividing the wafer 11 along the predetermined street 17, the cutting blade 8 is raised and the cutting blade 8 and the chuck table are next relatively moved (indexed) in a second direction perpendicular to the predetermined street 17, i.e., perpendicular to the first direction, thereby aligning the cutting blade 8 with the next street 17 extending in the first direction (indexing operation). Thereafter, the cutting blade 8 is lowered to cut into the wafer 11 and the cutting blade 8 and the chuck table are next relatively moved (fed) in the first direction parallel to this street 17. Accordingly, the wafer 11 can be divided along this street 17.

Such a feeding operation and an indexing operation are repeated to divide the wafer 11 along all of the streets 17 extending in the first direction. Thereafter, the chuck table (the wafer 11) is rotated 90 degrees to similarly perform the feeding operation and the indexing operation, thereby dividing the wafer 11 along all of the remaining streets 17 extending in the second direction perpendicular to the first direction. Thusly, the wafer 11 is divided along all of the streets 17 extending in both the first and second directions to thereby obtain the plural chips supported to the support member 21, then finishing the dividing step.

In the wafer processing method according to this preferred embodiment, the wafer 11 is fixed to the support member 21. Accordingly, the handleability of the wafer 11 divided into the plural chips can be maintained without the use of an annular frame as in the conventional processing method. In this case, the annular frame having a diameter larger than that of the wafer 11 can be omitted to thereby allow a reduction in size of the cutting apparatus 2. More specifically, it is possible to reduce the size of a transfer mechanism for transferring the wafer 11, the size of the chuck table for holding the wafer 11 under suction, and the size of a cassette elevator for mounting a cassette storing the wafer 11, for example.

The present invention is not limited to the above preferred embodiment, but various modifications may be made. For example, while a plate having a predetermined rigidity is used as the support member 21 in the above preferred embodiment, the support member usable in the present invention is not limited to the support member 21. FIG. 3 is a perspective view schematically showing a support member providing step using a support member 31 according to a modification.

As shown in FIG. 3, the support member 31 is an adhesive tape (film) having substantially the same size as that of the wafer 11. That is, an adhesive layer having tackiness (adhesive member) (not shown) is formed on the front side 31a of the support member 31. When this adhesive layer of the support member 31 is brought into contact with the back side 11b of the wafer 11, the support member 31 is attached to the back side 11b of the wafer 11.

In the subsequent dividing step, the unit of the wafer 11 and the support member 31 is held on the chuck table under suction in the condition where the back side 31b of the support member 31 is in contact with the chuck table. In this condition, the wafer 11 is divided by the cutting blade 8. In this method using an adhesive tape having substantially the same size as that of the wafer 11 as the support member 31, the chips obtained by the dividing step can be easily separated from the support member 31. Accordingly, troublesomeness in the subsequent pickup step can be reduced.

Further, while the dividing step in the wafer processing method according to this preferred embodiment is performed by using the cutting apparatus 2 for dicing the wafer 11 (blade dicing), the wafer processing method according to the present invention is not limited to this configuration. For example, the dividing step in the present invention may be performed by using a laser processing apparatus for dicing the wafer 11 (laser dicing). That is, the dicing applicable in the present invention includes not only the blade dicing of the wafer 11 by the cutting blade 8, but also the laser dicing of the wafer 11 by a laser beam. In any case, the wafer is fully cut over the entire thickness of the wafer 11.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method of processing a wafer having a plurality of devices formed on the front side of said wafer, said devices being respectively formed in a plurality of separate regions defined by a plurality of crossing division lines, said wafer processing method comprising:
a support member providing step of providing a support member on the back side of said wafer, said support member having substantially the same size as that of said wafer; and
a dividing step of dicing said wafer from the front side thereof along said division lines after performing said support member providing step, thereby dividing said wafer into a plurality of chips.

2. The wafer processing method according to claim 1, wherein said support member includes a plate, and said support member providing step includes the step of providing said plate on the back side of said wafer with an adhesive member interposed therebetween.
